(19) United States
(12) Patent Application Publication
(10) Pub. No.: US 2026/0246261 A1
(43) Pub. Date: Aug. 20, 2026

(54) ELECTROSTATIC DISCHARGE PROTECTION CIRCUIT AND INTEGRATED CIRCUIT HAVING ELECTROSTATIC DISCHARGE PROTECTION MECHANISM

(71) Applicants: Materials Analysis Technology Inc., Hsinchu County (TW); National Yang Ming Chiao Tung University, Hsinchu City (TW)

(72) Inventors: Chao-Yang Ke, New Taipei City (TW); Ming-Dou Ker, Hsinchu County (TW); HUNG-JEN CHEN, Hsinchu City (TW)

(21) Appl. No.: 19/408,295

(22) Filed: Dec. 3, 2025

Related U.S. Application Data
(60) Provisional application No. 63/760,192, filed on Feb. 19, 2025.

(51) Int. Cl. H02H 9/00; H02H 9/02

(52) U.S. Cl. CPC H02H 9/005; H02H 9/025

(57) ABSTRACT

An electrostatic discharge protection circuit in an integrated circuit implements an electrostatic discharge protection mechanism. The electrostatic discharge protection circuit detects the integrated circuit to determine whether or not an electrostatic discharge event occurs in the integrated circuit. When the electrostatic discharge event occurs in the integrated circuit, the electrostatic discharge circuit guides electrostatic discharge energy into the electrostatic discharge protection circuit and then guides the electrostatic discharge energy to a ground terminal outside the integrated circuit. The integrated circuit is prevented from being damaged by the electrostatic discharge energy.

### CROSS-REFERENCE TO RELATED PATENT APPLICATION

This application claims the benefit of priority to the U.S. Provisional Patent Application Ser. No. 63/760192, filed on February 19, 2025, which application is incorporated herein by reference in its entirety.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a protection circuit, and more particularly to an electrostatic discharge protection circuit and an integrated circuit having an electrostatic discharge protection mechanism.

### BACKGROUND OF THE DISCLOSURE

Gallium nitride (GaN) is a wide bandgap semiconductor material, particularly suitable for high-voltage, high-frequency, and high-efficiency applications. Therefore, replacing silicon (Si) with GaN as the material for circuit components in integrated circuits (ICs) is a technological trend that is gaining recognition in recent years.

GaN integrated circuits often include high electron mobility transistors (HEMTs) made of GaN. Although GaN inherently exhibits a relatively high breakdown voltage, it lacks sufficient electrostatic protection capability between a gate terminal and a channel of each HEMT. As a result, during an electrostatic discharge event in the integrated circuit, GaN components are susceptible to electrostatic damage.

### SUMMARY OF THE DISCLOSURE

In response to the above-referenced technical inadequacies, the present disclosure provides an electrostatic discharge protection circuit. The electrostatic discharge protection circuit is applicable to an integrated circuit. The electrostatic discharge protection circuit includes an electrostatic discharge clamp circuit. The electrostatic discharge clamp circuit is connected to the integrated circuit and an external ground terminal. The electrostatic discharge clamp circuit is configured to detect the integrated circuit to determine whether or not an electrostatic discharge event occurs in the integrated circuit. When the electrostatic discharge event occurs in the integrated circuit, the electrostatic discharge clamp circuit is configured to guide electrostatic energy inside the integrated circuit to the electrostatic discharge clamp circuit, and then guide the electrostatic energy to the external ground terminal outside the integrated circuit.

In order to solve the above-mentioned problems, one of the technical aspects adopted by the present disclosure is to provide an electrostatic discharge protection circuit. The electrostatic discharge protection circuit is applicable to a driver circuit. The driver circuit includes a plurality of input terminals. The plurality of input terminals includes a plurality of power receiving terminals. The electrostatic discharge protection circuit includes an electrostatic discharge clamp circuit. The electrostatic discharge clamp circuit is connected to the plurality of power receiving terminals and an external ground terminal. The electrostatic discharge clamp circuit is configured to detect a power signal at each of the plurality of power receiving terminals to determine whether or not an electrostatic discharge event occurs in the driver circuit. The electrostatic discharge clamp circuit is configured to guide electrostatic energy to the electrostatic discharge clamp circuit and then guide the electrostatic energy to the external ground terminal outside the driver circuit when the electrostatic discharge event occurs in the driver circuit.

In order to solve the above-mentioned problems, one of the technical aspects adopted by the present disclosure is to provide an integrated circuit having an electrostatic discharge protection mechanism. The integrated circuit includes a driver circuit and an electrostatic discharge clamp circuit. The driver circuit includes a plurality of input terminals. The plurality of input terminals includes a plurality of power receiving terminals. The electrostatic discharge clamp circuit is connected to the plurality of power receiving terminals and an external ground terminal. The electrostatic discharge clamp circuit is configured to detect a power signal at each of the plurality of power receiving terminals to determine whether or not an electrostatic discharge event occurs in the driver circuit. The electrostatic discharge clamp circuit is configured to guide electrostatic energy inside the integrated circuit to the electrostatic discharge clamp circuit and then guide the electrostatic energy to the external ground terminal outside the integrated circuit when the electrostatic discharge event occurs in the driver circuit.

As described above, the present disclosure provides the electrostatic discharge protection circuit and the integrated circuit having the electrostatic discharge protection mechanism. The electrostatic discharge protection circuit of the present disclosure is applied to the integrated circuit, in particular a GaN integrated circuit, to perform detection that effectively prevents both transient leakage during normal or rapid power-up and steady-state leakage in a standby mode, thereby reducing power consumption and improving the long-term reliability of the integrated circuit.

These and other aspects of the present disclosure will become apparent from the following description of the embodiment taken in conjunction with the following drawings and their captions, although variations and modifications therein may be effected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a circuit diagram of an integrated circuit including an electrostatic discharge protection circuit according to a first embodiment of the present disclosure;

FIG. 2 is a schematic diagram of an electrostatic discharge path of the electrostatic discharge protection circuit applied to the integrated circuit according to the first embodiment of the present disclosure;

FIG. 3 is a schematic diagram of an electrostatic discharge path of the electrostatic discharge protection circuit applied to the integrated circuit according to the first embodiment of the present disclosure;

FIG. 4 is a schematic diagram of an electrostatic discharge path of the electrostatic discharge protection circuit applied to the integrated circuit according to the first embodiment of the present disclosure;

FIG. 5 is a schematic diagram of an electrostatic discharge path of the electrostatic discharge protection circuit applied to the integrated circuit according to the first embodiment of the present disclosure;

FIG. 6 is a schematic diagram of an electrostatic discharge path of the electrostatic discharge protection circuit applied to the integrated circuit according to the first embodiment of the present disclosure;

FIG. 7 is a schematic diagram of an electrostatic discharge path of the electrostatic discharge protection circuit applied to the integrated circuit according to the first embodiment of the present disclosure;

FIG. 8 is a circuit diagram of an electrostatic discharge protection circuit according to a second embodiment of the present disclosure;

FIG. 9 is a circuit diagram of an electrostatic discharge clamp circuit of an electrostatic discharge protection circuit according to a third embodiment of the present disclosure;

FIG. 10 is a circuit diagram of an electrostatic discharge clamp circuit of an electrostatic discharge protection circuit according to a fourth embodiment of the present disclosure; and

FIG. 11 is a circuit diagram of an electrostatic discharge clamp circuit of an electrostatic discharge protection circuit according to a fifth embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an”, and “the” includes plural reference, and the meaning of “in” includes “in” and “on”. Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, signals or the like, which are for distinguishing one component/signal from another one only, and are not intended to, nor should be construed to impose any substantive limitations on the components, signals or the like.

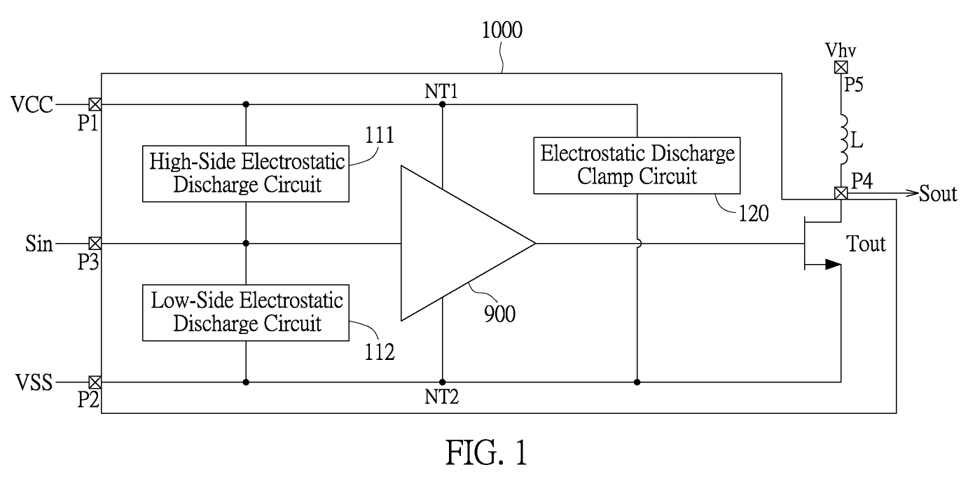

Reference is made to FIG. 1, which is a circuit diagram of an integrated circuit including an electrostatic discharge (ESD) protection circuit according to a first embodiment of the present disclosure.

The electrostatic discharge protection circuit is applicable to an integrated circuit 1000 or disposed inside the integrated circuit 1000, and is particularly suitable for the integrated circuit 1000 made of gallium nitride (GaN).

The electrostatic discharge protection circuit includes an electrostatic discharge clamp circuit 120. The electrostatic discharge clamp circuit 120 is connected to the integrated circuit 1000 and an external ground terminal.

When an electrostatic discharge event occurs, a very short but high-energy electromagnetic pulse, spike, or surge is generated, which causes circuit components inside the integrated circuit to be damaged. Therefore, the electrostatic discharge clamp circuit 120 of the present disclosure detects a power signal inside the integrated circuit 1000. Then, the electrostatic discharge clamp circuit 120 determines whether an abnormal instantaneous change occurs in the power signal (including a voltage signal, a current signal, or a combination thereof) and whether the abnormal instantaneous change meets a preset electrostatic abnormal change, and accordingly determines whether or not an electrostatic discharge event occurs in the integrated circuit 1000. When the abnormal instantaneous change occurs in the power signal and the abnormal instantaneous change meets the preset electrostatic abnormal change, the electrostatic discharge clamp circuit 120 determines that the electrostatic discharge event occurs in the integrated circuit 1000.

More specifically, when power of the power signal (such as a voltage signal or a current signal) inside the integrated circuit 1000 exceeds a power protection threshold (such as a voltage threshold or a current threshold), the electrostatic discharge clamp circuit 120 determines that the abnormal instantaneous change occurs and the abnormal instantaneous change meets the preset electrostatic abnormal change. The electrostatic discharge clamp circuit 120 discharges the power signal before the power signal is increased to exceed a maximum withstand voltage and a maximum withstand current of circuit components inside the integrated circuit, thereby preventing these circuit components from being damaged by instantaneous high voltage or large current.

For a clearer understanding, an example is provided below to illustrate how the power signal in the integrated circuit 1000 is detected.

For example, a plurality of pins of the integrated circuit 1000 may include a first power pin P1, a second power pin P2, a signal input pin P3 and a signal output pin P4. The integrated circuit 1000 using or including the electrostatic discharge protection circuit of the present disclosure may include a driver circuit 900, and an output stage circuit such as an output transistor Tout shown in FIG. 1. The driver circuit 900 may include an operational amplifier, an error amplifier, a buffer, or other circuit components.

The driver circuit 900 may include a plurality of input terminals, such as but not limited to a plurality of power receiving terminals, one or more signal input terminals, and a signal output terminal. Each of the plurality of power receiving terminals of the driver circuit 900 is coupled to an input power source. For example, the plurality of power receiving terminals of the driver circuit 900 include a first power receiving terminal and a second power receiving terminal. The first power receiving terminal is connected to the first input node NT1, and the first input node NT1 is further connected to a first input power source VCC through the first power pin P1. The second power receiving terminal is connected to the second input node NT2, and the second input node NT2 is further connected to a second input power source VSS through the second power pin P2.

A control terminal of the output transistor Tout is connected to an output terminal of the driver circuit 900. A first terminal of the output transistor Tout is connected to a second terminal of the output inductor L and the signal output pin P4 of the integrated circuit 1000. A first terminal of the output inductor L is connected to a third power pin P5. A second terminal of the output transistor Tout is connected to the second input power source VSS through the second power pin P2 of the integrated circuit 1000.

In the integrated circuit 1000, the driver circuit 900 outputs an output signal to the control terminal of the output transistor Tout according to an input signal Sin, so as to drive the output transistor Tout to operate. When the output transistor Tout is turned on, an input current flows from a third input power source Vhv through the third power pin P5 into the output inductor L, and then flows through the output transistor Tout. A signal between the second terminal of the output inductor L and the first terminal of the output transistor Tout may be outputted as an output signal Sout (such as an output voltage signal) to an external circuit through the signal output pin P4 of the integrated circuit 1000.

A first terminal of the electrostatic discharge clamp circuit 120 is connected to the first power pin P1 of the integrated circuit 1000, the first power receiving terminal of the driver circuit 900 of the integrated circuit 1000, and the first input node NT1. A second terminal of the electrostatic discharge clamp circuit 120 is connected to the second power pin P2 of the integrated circuit 1000, the second power receiving terminal of the driver circuit 900 of the integrated circuit 1000, and the second input node NT2.

The electrostatic discharge clamp circuit 120 may detect the power signal at one or more pins of the integrated circuit 1000 (such as the first power pin P1 and the second power pin P2), the first power receiving terminal and the second power receiving terminal of the driver circuit 900, or one or more nodes (such as the first input node NT1 and the second input node NT2) connected thereto. Then, the electrostatic discharge clamp circuit 120 may, according to the power signal that is detected, determine whether or not the electrostatic discharge event occurs in the integrated circuit 1000.

It is worth noting that, when the electrostatic discharge clamp circuit 120 determines that the electrostatic discharge event occurs, the electrostatic discharge clamp circuit 120 guides electrostatic energy of the integrated circuit 1000 to the electrostatic discharge clamp circuit 120, and then guides the electrostatic energy to the external ground terminal outside the integrated circuit 1000. The external ground terminal may be connected to any of the plurality of pins of the integrated circuit 1000. The external ground terminal described herein may be a ground terminal or a reference potential terminal having a reference voltage level (such as a low voltage level).

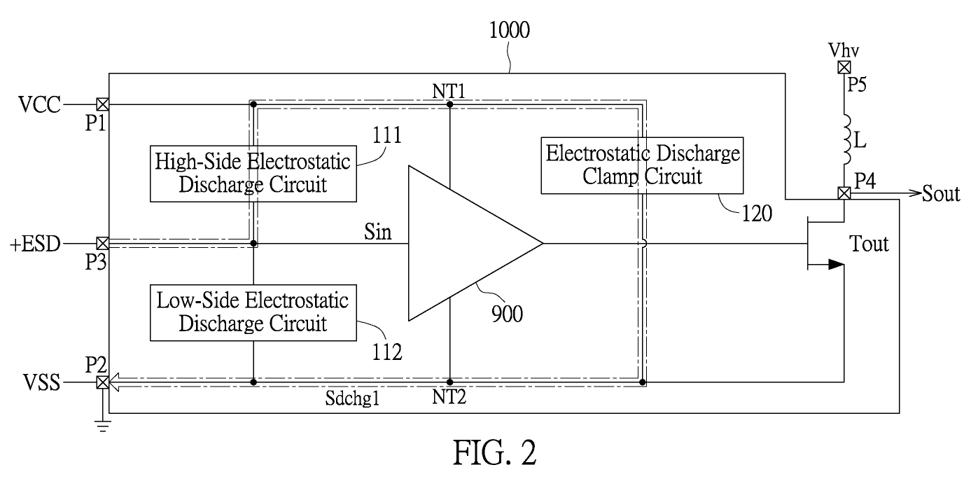

Reference is made to FIG. 1 to FIG. 7, in which FIG. 2 to FIG. 7 are schematic diagrams of electrostatic discharge paths of the electrostatic discharge protection circuit applied to the integrated circuit according to the first embodiment of the present disclosure.

In order to have a better electrostatic discharge effect to improve stability of the integrated circuit 1000, for example, as shown in FIG. 1, the electrostatic discharge protection circuit of the present disclosure not only includes the electrostatic discharge clamp circuit 120, but may further include a high-side electrostatic discharge circuit 111 and a low-side electrostatic discharge circuit 112 for providing a plurality of electrostatic discharge paths.

A first terminal of the high-side electrostatic discharge circuit 111 is connected to the first power pin P1 and the first input node NT1. A second terminal of the high-side electrostatic discharge circuit 111 and a first terminal of the low-side electrostatic discharge circuit 112 are connected to the signal input pin P3. A second terminal of the low-side electrostatic discharge circuit 112 is connected to the second power pin P2 of the integrated circuit 1000 and the second input node NT2.

The electrostatic discharge clamp circuit 120, the high-side electrostatic discharge circuit 111 and the low-side electrostatic discharge circuit 112 that are included in the electrostatic discharge protection circuit of the present disclosure are all used to quickly guide an electrostatic discharge current generated by the electrostatic discharge event to outside of the integrated circuit 1000. As a result, the electrostatic discharge current does not flow into a core circuit (including the driver circuit 900) of the integrated circuit 1000, thereby preventing electronic components from being damaged by electrostatic discharge.

As shown in FIG. 2, in a positive-to-VSS mode (PS-mode) in which a positive-voltage electrostatic discharge is zapping onto an input/output (IO) pin and a VSS pin is grounded, positive-voltage electrostatic energy Sdchg1 (such as an electrostatic discharge current) is input from the signal input pin P3 (that is used as the IO pin) of the integrated circuit 1000 into the integrated circuit 1000. Under this condition, the second power pin P2 (that is used as the VSS pin) of the integrated circuit 1000 is connected to the external ground terminal outside the integrated circuit 1000, and the high-side electrostatic discharge circuit 111 and the electrostatic discharge clamp circuit 120 are turned on. As a result, the positive-voltage electrostatic energy Sdchg1 flows or is guided along a first one of the plurality of electrostatic discharge paths sequentially to the high-side electrostatic discharge circuit 111 and to the electrostatic discharge clamp circuit 120, and then flows through or is guided to the second power pin P2 of the integrated circuit 1000 to the external ground terminal.

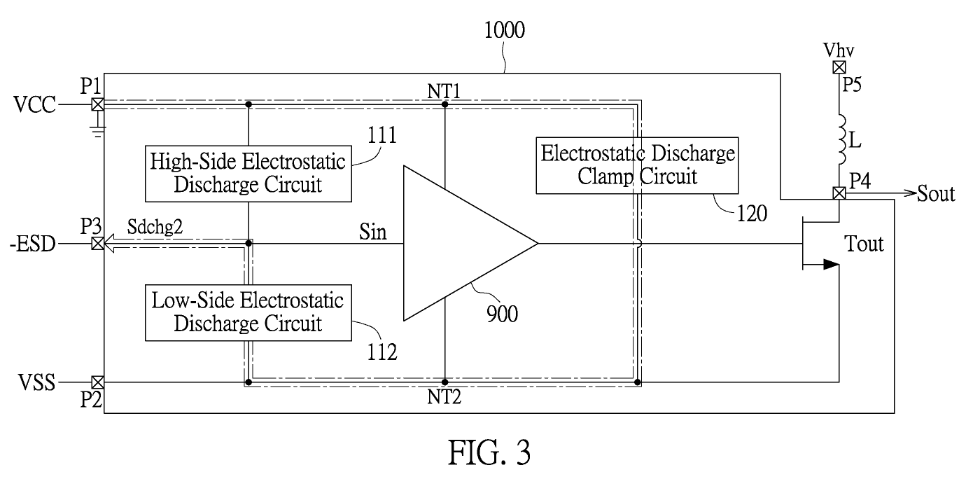

As shown in FIG. 3, in a negative-to-VDD mode (ND-mode) in which a negative-voltage electrostatic discharge is zapping onto the IO pin and a VCC pin (or a VDD pin) is grounded, a negative-voltage electrostatic energy Sdchg2 is input from the signal input pin P3 of the integrated circuit 1000 into the integrated circuit 1000. Under this condition, the first power pin P1 (that is used as the VCC pin) of the integrated circuit 1000 is grounded, and the low-side electrostatic discharge circuit 112 and the electrostatic discharge clamp circuit 120 are turned on. As a result, the negative-voltage electrostatic energy Sdchg2 flows through or is guided along a second one of the plurality of electrostatic discharge paths, sequentially to the electrostatic discharge clamp circuit 120 and the low-side electrostatic discharge circuit 112, and then flows through or is guided to the signal input pin P3 of the integrated circuit 1000 to an external discharge terminal (such as a reference voltage level terminal having a negative voltage level) outside the integrated circuit 1000.

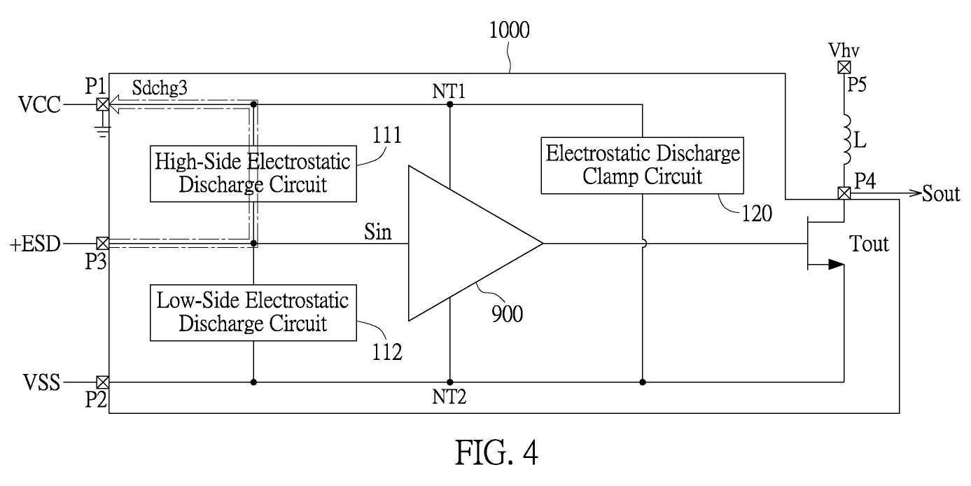

As shown in FIG. 4, in a positive-to-VDD mode (PD-mode) in which the positive-voltage electrostatic discharge is zapping onto the IO pin and the VDD pin (or the VDD pin) is grounded, positive-voltage electrostatic energy Sdchg3 (such as an electrostatic discharge current) is input from a pin such as the signal input pin P3 of the integrated circuit 1000 into the integrated circuit 1000. Under this condition, the first power pin P1 of the integrated circuit 1000 is grounded, and the high-side electrostatic discharge circuit 111 is turned on. As a result, the positive-voltage electrostatic energy Sdchg3 flows through or is guided along a third one of the plurality of electrostatic discharge paths, to the high-side electrostatic discharge circuit 111 and then flows or is transmitted to the external ground terminal outside the integrated circuit 1000 through the first power pin P1 of the integrated circuit 1000.

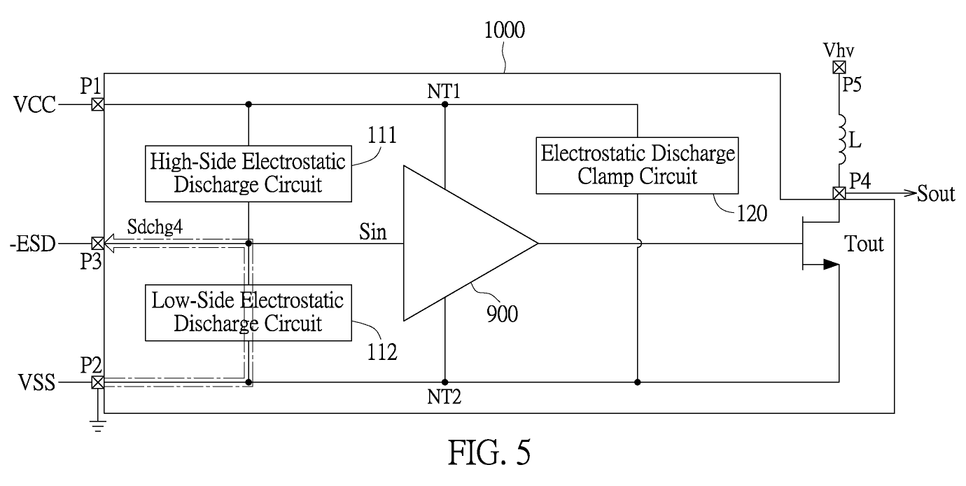

As shown in FIG. 5, in a negative-to-VSS mode (NS-mode) in which the negative-voltage electrostatic discharge is zapping onto the IO pin and the VSS pin is grounded, a negative-voltage electrostatic energy Sdchg4 (such as an electrostatic discharge current) is input from the signal input pin P3 of the integrated circuit 1000 into the integrated circuit 1000. Under this condition, the low-side electrostatic discharge circuit 112 is turned on. As a result, the negative-voltage electrostatic energy Sdchg4 flows through or is guided along a fourth one of the plurality of electrostatic discharge paths, to the low-side electrostatic discharge circuit 112 and then flows or is transmitted through the signal input pin P3 of the integrated circuit 1000 to the external discharge terminal (such as the reference voltage level terminal having the negative voltage level) outside the integrated circuit 1000.

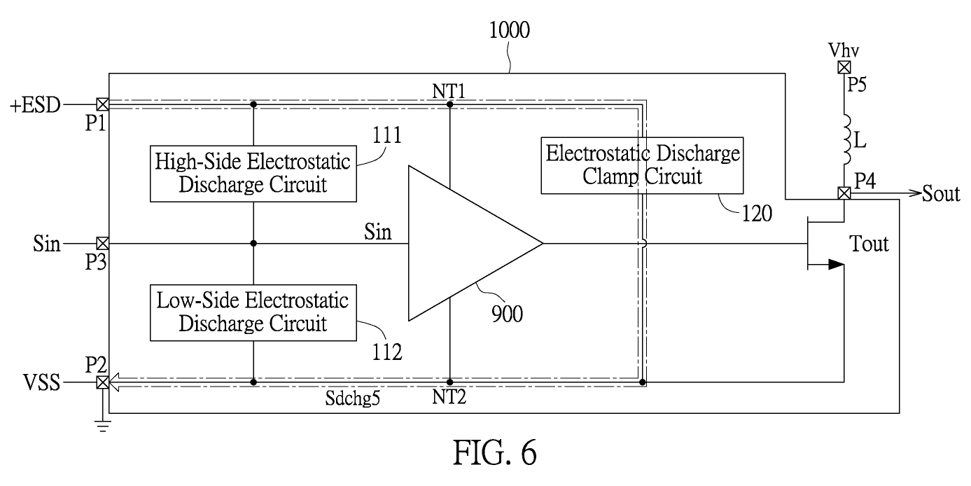

As shown in FIG. 6, in a positive mode in which the positive voltage electrostatic discharge is zapping onto the VCC pin and the VSS pin is grounded, positive-voltage electrostatic energy Sdchg5 is input into the integrated circuit 1000 from the first power supply pin P1 (that is used as the VCC pin) of the integrated circuit 1000. Under this condition, the second power pin P2 of the integrated circuit 1000 is grounded, and the electrostatic discharge clamp circuit 120 is turned on. As a result, the positive-voltage electrostatic energy Sdchg5 flows through or is guided, along a fifth one of the plurality of electrostatic discharge paths, to the electrostatic discharge clamp circuit 120 and then flows through or is guided through the second power pin P2 of the integrated circuit 1000 to the external ground terminal outside the integrated circuit 1000.

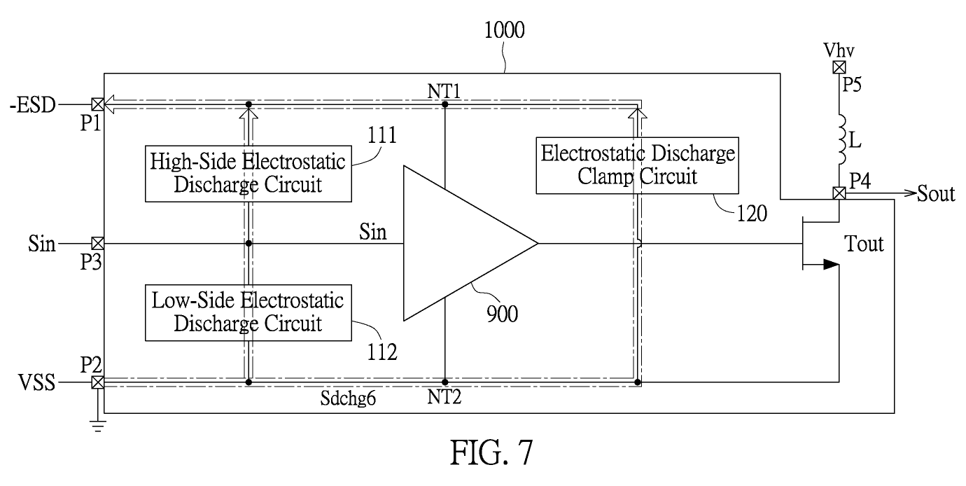

As shown in FIG. 7, in a negative-mode in which the negative voltage electrostatic discharge is zapping onto the VCC pin and the VSS pin is grounded, negative voltage electrostatic energy Sdchg6 is input from the first power pin P1 of the integrated circuit 1000 into the integrated circuit 1000. Under this condition, the second power pin P2 of the integrated circuit 1000 is grounded, and the electrostatic discharge clamp circuit 120, the high-side electrostatic discharge circuit 111 and the low-side electrostatic discharge circuit 112 are turned on. As a result, one part of the negative voltage electrostatic energy Sdchg6 flows or is guided along a first electrostatic discharge branch path to the electrostatic discharge clamp circuit 120, and the other part of the negative voltage electrostatic energy Sdchg6 flows or is guided along a second electrostatic discharge branch path to the low-side electrostatic discharge circuit 112 and the high-side electrostatic discharge circuit 111. Then, all the negative voltage electrostatic energy Sdchg6 flows or is guided through the first power pin P1 (that is used as the VCC pin) of the integrated circuit 1000 to the external discharge terminal (such as the reference voltage level terminal having the negative voltage level) outside the integrated circuit 1000.

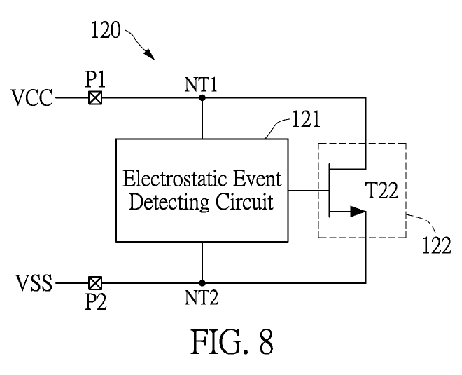

Reference is made to FIG. 8, which is a circuit diagram of an electrostatic discharge protection circuit according to a second embodiment of the present disclosure. The electrostatic discharge clamp circuit 120 in FIG. 1 to FIG. 5 may include an electrostatic discharge event detecting circuit 121 and an electrostatic discharge path circuit 122 as shown in FIG. 8.

The electrostatic discharge path circuit 122 may include a switch component as an electrostatic discharge switch T22, which may be a transistor.

A first terminal of the electrostatic discharge path circuit 122 is connected to the first power pin P1. A second terminal of the electrostatic discharge path circuit 122 is connected to the second power pin P2.

The electrostatic discharge event detecting circuit 121 is connected between the first input node NT1 and the second input node NT2 inside the integrated circuit 1000, and is connected to a control terminal of the electrostatic discharge path circuit 122.

The electrostatic discharge event detecting circuit 121 detects the power signal at the first input node NT1 or the second input node NT2 inside the integrated circuit 1000 to determine whether or not the electrostatic discharge event occurs in the integrated circuit 1000. When the electrostatic discharge event detecting circuit 121 determines that the electrostatic discharge event does not occur in the integrated circuit 1000, the electrostatic discharge event detecting circuit 121 turns on the electrostatic discharge path circuit 122.

When the electrostatic discharge event detecting circuit 121 determines that the electrostatic discharge event occurs in the integrated circuit 1000, the electrostatic discharge event detecting circuit 121 turns on the electrostatic discharge switch T22, such that the electrostatic discharge switch T2 provides an electrostatic discharge path along which the electrostatic discharge energy flows through the electrostatic discharge switch T22 to the external ground terminal. More precisely, the electrostatic discharge event detecting circuit 121 may also control a conduction state of the electrostatic discharge switch T22 according to an amount of the power signal that is detected, so as to control an amount of the electrostatic discharge current flowing through the electrostatic discharge switch T22 per unit time, thereby controlling a rate of electrostatic discharge.

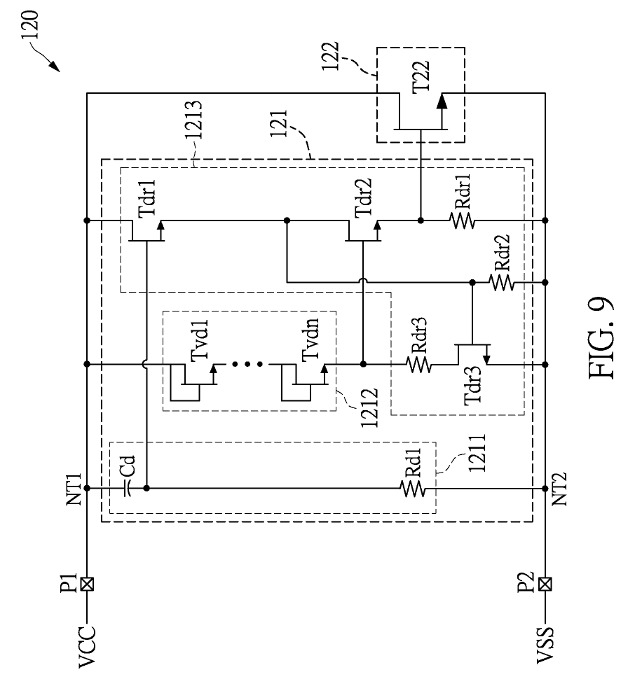

Reference is made to FIG. 9, which is a circuit diagram of an electrostatic discharge clamp circuit of an electrostatic discharge protection circuit according to a third embodiment of the present disclosure. The descriptions of the third to fifth embodiments of the present disclosure that are the same as the descriptions of the first and second embodiments are not repeated herein.

The electrostatic discharge event detecting circuit 121 shown in FIG. 8 may be the same as that shown in FIG. 9. As shown in FIG. 9, the electrostatic discharge event detecting circuit 121 may include a charging time detecting circuit 1211, a voltage detecting circuit 1212 and an electrostatic discharge starting circuit 1213.

The charging time detecting circuit 1211 is connected to the first power pin P1 and the second power pin P2, connected between the first input node NT1 and the second input node NT2, or connected to the plurality of power receiving terminals of the driver circuit 900 shown in FIG. 1 to FIG. 5.

When the charging time detecting circuit 1211 detects and determines that the electrostatic energy between the first power pin P1 and the second power pin P2, at the first input node NT1, at the second input node NT2 or at the power receiving terminals of the driver circuit 900 is coupled to the startup voltage level after a charging time has elapsed, the charging time detecting circuit 1211 outputs a detection time startup signal (such as, but not limited to, a high voltage level signal).

The voltage detecting circuit 1212 is connected to the first power pin P1 and the second power pin P2, or is connected between the first input node NT1 and the second input node NT2. When the voltage detecting circuit 1212 detects and determines that a voltage level at a detection node between the first power pin P1 and the second power pin P2 or between the first input node NT1 and the second input node NT2 reaches the startup voltage level, the voltage detecting circuit 1212 outputs the overvoltage signal (such as, but not limited to, the high voltage level signal).

The electrostatic discharge starting circuit 1213 is connected to the charging time detecting circuit 1211, the voltage detecting circuit 1212 and the electrostatic discharge path circuit 122. The electrostatic discharge starting circuit 1213, according to the detection time startup signal from the charging time detecting circuit 1211 and the overvoltage signal from the voltage detecting circuit 1212, outputs an electrostatic discharge starting signal (such as, but not limited to a high voltage level signal) to a control terminal of the electrostatic discharge switch T22 of the electrostatic discharge path circuit 122 to turn on the electrostatic discharge path circuit 122.

The configuration inside the charging time detecting circuit 1211, the voltage detecting circuit 1212 and the electrostatic discharge starting circuit 1213 that are included in the electrostatic discharge event detecting circuit 121 of the electrostatic discharge protection circuit of the present disclosure may depend on actual requirements, as exemplified below and shown in FIGS. 9, 10, and 11.

The charging time detecting circuit 1211 includes a charging capacitor Cd and a charging resistor Rd1 as shown in FIG. 9, or in practice, includes other circuit components, as a plurality of charged components. The voltage detecting circuit 1212 includes one or more switch components such as, but not limited to a plurality of voltage detection transistors Tvd1 to Tvdn. The electrostatic discharge starting circuit 1213 includes one or more switch components such as, but not limited to a startup switch component Tdr1 and a driving switch component Tdr2 that may be transistors. If necessary, as shown in FIG. 9, the electrostatic discharge starting circuit 1213 may further include a first startup modulation resistor Rdr1, a second startup modulation resistor Rdr2, a third startup modulation resistor Rdr3, a startup modulation transistor Tdr3 or any combination thereof.

The charging capacitor Cd and the charging resistor Rd1 are connected in series between the first input node NT1 and the second input node NT2. A first terminal of the charging capacitor Cd is connected to the first power pin P1 and the first input node NT1. A second terminal of the charging capacitor Cd is connected to a first terminal of the charging resistor Rd1. A second terminal of the charging resistor Rd1 is connected to the second power pin P2 and the second input node NT2.

A control terminal of the startup switch component Tdr1 is connected to a voltage node between the second terminal of the charging capacitor Cd and the first terminal of the charging resistor Rd1. A first terminal of the startup switch component Tdr1 is connected to the first power pin P1 and the first input node NT1. A second terminal of the startup switch component Tdr1 is connected to a first terminal of the driving switch component Tdr2.

The plurality of voltage detection transistors Tvd1 to Tvdn are arranged sequentially. A first terminal of the voltage detection transistor Tvd1 that is a first one of the plurality of voltage detection transistors Tvd1 to Tvdn is used as an input terminal of the voltage detecting circuit 1212, and is connected to the first power pin P1 and the first input node NT1. A first terminal and a control terminal of each of the plurality of voltage detection transistors Tvd2 to Tvdn are connected to a second terminal of a previous one of the plurality of voltage detection transistors Tvd1 to Tvdn. A second terminal of the last one of the plurality of voltage detection transistors Tvd1 to Tvdn is used as an output terminal of the voltage detecting circuit 1212, and is connected to a control terminal of the driving switch component Tdr2.

A second terminal of the driving switch component Tdr2 is connected to the control terminal of the electrostatic discharge switch T22.

The control terminal of the electrostatic discharge switch T22 may be further connected to a first terminal of the first startup modulation resistor Rdr1. The first terminal of the first startup modulation resistor Rdr1 is connected to the second terminal of the driving switch component Tdr2. A control terminal of the startup modulation transistor Tdr3 may be connected to a first terminal of the second startup modulation resistor Rdr2. The control terminal of the driving switch component Tdr2 may be connected to a first terminal of the third startup modulation resistor Rdr3. A first terminal of the startup modulation transistor Tdr3 may be connected to a second terminal of the third startup modulation resistor Rdr3.

A second terminal of the startup modulation transistor Tdr3, a second terminal of the second startup modulation resistor Rdr2, a second terminal of the first startup modulation resistor Rdr1 and a second terminal of the electrostatic discharge switch T22 are connected to the second power pin P2 and the second input node NT2.

When the electrostatic energy is zapping onto the first power pin P1, the charging capacitor Cd and the charging resistor Rd1 is charged by the power signal of the first power pin P1 of the integrated circuit 1000 such that a voltage at the voltage node between the second terminal of the charging capacitor Cd and the first terminal of the charging resistor Rd1 is gradually increased. When the voltage at the voltage node is gradually increased to the startup voltage level after the charging time has elapsed, the startup switch component Tdr1 is turned on.

When the startup switch component Tdr1 is turned on, a voltage of the second startup modulation resistor Rdr2 is increased to turn on the startup modulation transistor Tdr3, and an electrostatic discharge voltage is increased to turn on the plurality of voltage detection transistors Tvd1 to Tvdn. At this time, a voltage of the third startup modulation resistor Rdr3 is increased to turn on the driving switch component Tdr2. The power signal flows from the first input node NT1 sequentially through the startup switch component Tdr1, the driving switch component Tdr2 and the first startup modulation resistor Rdr1. As a result, a voltage of the startup switch component Tdr1, which is inputted to the control terminal of the electrostatic discharge switch T22, is increased. When the electrostatic discharge switch T22 is turned on, electrostatic energy flows sequentially through the electrostatic discharge switch T22 and the second power pin P2 of the integrated circuit 1000, and then flows to the external ground terminal or flows through the second input power source VSS having the low voltage level or a zero voltage level to the external ground terminal.

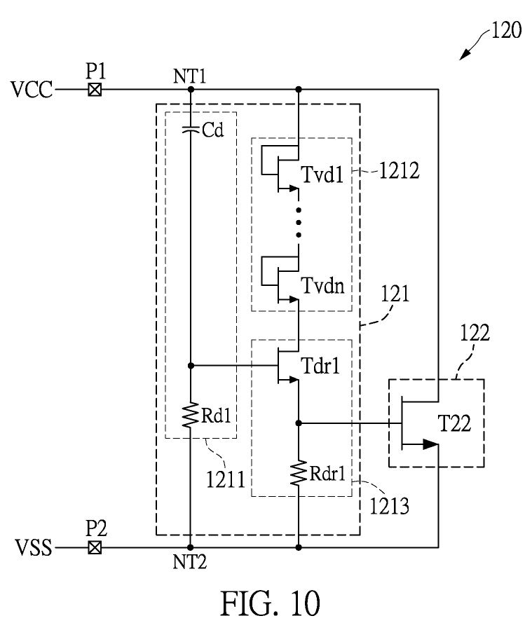

Reference is made to FIG. 10, which is a circuit diagram of an electrostatic discharge clamp circuit of an electrostatic discharge protection circuit according to a fourth embodiment of the present disclosure. The descriptions of the fourth embodiment that are the same as the descriptions of the third embodiment are not repeated herein.

The control terminal of the startup switch component Tdr1 is connected to the voltage node between the second terminal of the charging capacitor Cd and the first terminal of the charging resistor Rd1. The first terminal of the voltage detection transistor Tvd1 is connected to the first power pin P1 of the integrated circuit 1000 and the first input node NT1.

The first terminal of the startup switch component Tdr1 is connected to a second terminal of the voltage detection transistor Tvdn. The second terminal of the startup switch component Tdr1 is connected to the control terminal of the electrostatic discharge switch T22 and the first terminal of the first startup modulation resistor Rdr1.

The second terminal of the charging resistor Rd1, the second terminal of the first startup modulation resistor Rdr1 and the second terminal of the electrostatic discharge switch T22 are connected to the second power pin P2 and the second input node NT2.

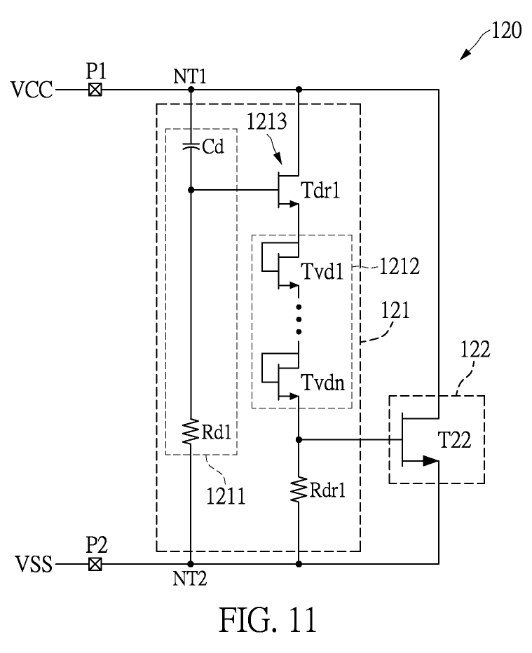

Reference is made to FIG. 11, which is a circuit diagram of an electrostatic discharge clamp circuit of an electrostatic discharge protection circuit according to a fifth embodiment of the present disclosure. The descriptions of the fifth embodiment that are the same as the descriptions of the third embodiment are not repeated herein.

The first terminal of the startup switch component Tdr1 is connected to the first power pin P1. The control terminal of the startup switch component Tdr1 is connected to the voltage node between the second terminal of the charging capacitor Cd and the first terminal of the charging resistor Rd1. The second terminal of the startup switch component Tdr1 is connected to the first terminal of the voltage detection transistor Tvd1. The second terminal of the voltage detection transistor Tvdn is connected to the control terminal of the electrostatic discharge switch T22 and the first terminal of the first startup modulation resistor Rdr1.

The second terminal of the charging resistor Rd1, the second terminal of the first startup modulation resistor Rdr1 and the second terminal of the electrostatic discharge switch T22 are connected to the second power pin P2 or the second input node NT2.

In conclusion, the present disclosure provides the electrostatic discharge protection circuit and the integrated circuit having the electrostatic discharge protection mechanism. The electrostatic discharge protection circuit of the present disclosure is applied to the integrated circuit, in particular a GaN integrated circuit, to perform detection that effectively prevents both transient leakage during normal or rapid power-up and steady-state leakage in a standby mode, thereby reducing power consumption and improving the long-term reliability of the integrated circuit.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. An electrostatic discharge protection circuit, which is applicable to an integrated circuit, comprising:
an electrostatic discharge clamp circuit connected to the integrated circuit and an external ground terminal, and configured to detect the integrated circuit to determine whether or not an electrostatic discharge event occurs in the integrated circuit;
wherein, when the electrostatic discharge event occurs in the integrated circuit, the electrostatic discharge clamp circuit is configured to guide electrostatic energy inside the integrated circuit to the electrostatic discharge clamp circuit, and then guide the electrostatic energy to the external ground terminal outside the integrated circuit.

2. The electrostatic discharge protection circuit according to claim 1, wherein the electrostatic discharge clamp circuit is connected to a plurality of pins of the integrated circuit, and configured to detect the electrostatic energy at one or more of the plurality of pins or one or more nodes connected thereto to determine whether or not the electrostatic discharge event occurs in the integrated circuit.

3. The electrostatic discharge protection circuit according to claim 2, wherein the electrostatic discharge clamp circuit includes:
an electrostatic discharge path circuit connected to the plurality of pins, and connected to the external ground terminal through one of the plurality of pins; and
an electrostatic discharge event detecting circuit connected to the integrated circuit and the electrostatic discharge path circuit, wherein the electrostatic discharge event detecting circuit is configured to detect the integrated circuit, and to turn on the electrostatic discharge path circuit when the electrostatic discharge event detecting circuit determines that the electrostatic discharge event occurs in the integrated circuit.

4. The electrostatic discharge protection circuit according to claim 3, wherein the plurality of pins of the integrated circuit include a first power pin and a second power pin, and the electrostatic discharge event detecting circuit includes:
a charging time detecting circuit connected between the first power pin and the second power pin, and configured to output a detection time startup signal when the charging time detecting circuit detects and determines that a power signal between the first power pin and the second power pin is coupled to a startup voltage level after a charging time has elapsed;
a voltage detecting circuit connected between the first power pin and the second power pin, and configured to output an overvoltage signal when the voltage detecting circuit detects and determines that a voltage level of the power signal reaches the startup voltage level; and
an electrostatic discharge starting circuit connected to the charging time detecting circuit, the voltage detecting circuit and the electrostatic discharge path circuit, and configured to turn on the electrostatic discharge path circuit according to the detection time startup signal and the overvoltage signal.

5. The electrostatic discharge protection circuit according to claim 4, wherein the charging time detecting circuit includes a plurality of charged components, and the electrostatic discharge starting circuit includes a startup switch component and a driving switch component;
wherein the plurality of charged components are connected in series between the first power pin and the second power pin, a control terminal of the startup switch component is connected to a voltage node between two of the plurality of charged components, and a first terminal of the startup switch component and an input terminal of the voltage detecting circuit are connected to the first power pin;
wherein an output terminal of the voltage detecting circuit is connected to a control terminal of the driving switch component, a first terminal of the driving switch component is connected to a second terminal of the startup switch component, and a second terminal of the driving switch component is connected to a control terminal of the electrostatic discharge path circuit.

6. The electrostatic discharge protection circuit according to claim 4, wherein the charging time detecting circuit includes a plurality of charged components, and the electrostatic discharge starting circuit includes a startup switch component;
wherein the plurality of charged components are connected in series between the first power pin and the second power pin, and an input terminal of the voltage detecting circuit is connected to the first power pin;
wherein a control terminal of the startup switch component is connected to a voltage node between two of the plurality of charged components, a first terminal of the startup switch component is connected to an output terminal of the voltage detecting circuit, and a second terminal of the startup switch component is connected to a control terminal of the electrostatic discharge path circuit.

7. The electrostatic discharge protection circuit according to claim 4, wherein the charging time detecting circuit includes a plurality of charged components, and the electrostatic discharge starting circuit includes a startup switch component;
wherein the plurality of charged components are connected in series between the first power pin and the second power pin, a first terminal of the startup switch component is connected to the first power pin, a control terminal of the startup switch component is connected to a voltage node between two of the plurality of charged components, a second terminal of the startup switch component is connected to an input terminal of the voltage detecting circuit, and an output terminal of the voltage detecting circuit is connected to a control terminal of the electrostatic discharge path circuit.

8. An electrostatic discharge protection circuit, which is applicable to a driver circuit, wherein the driver circuit includes a plurality of input terminals, the plurality of input terminals includes a plurality of power receiving terminals, and the electrostatic discharge protection circuit comprising:
an electrostatic discharge clamp circuit connected to the plurality of power receiving terminals and an external ground terminal, and configured to:
detect a power signal at each of the plurality of power receiving terminals to determine whether an electrostatic discharge event occurs in the driver circuit; and
guide electrostatic energy to the electrostatic discharge clamp circuit and then guide the electrostatic energy to the external ground terminal outside the driver circuit when the electrostatic discharge event occurs in the driver circuit.

9. The electrostatic discharge protection circuit according to claim 8, wherein the plurality of power receiving terminals include a first power receiving terminal and a second power receiving terminal, the first power receiving terminal is connected to a first input node and the first input node is connected to a first input power source, the second power receiving terminal is connected to a second input node, and the second input node is connected to a second input power source, and the electrostatic discharge clamp circuit includes:
an electrostatic discharge path circuit connected between the first input node and the second input node; and
an electrostatic discharge event detecting circuit connected between the first input node and the second input node and connected to a control terminal of the electrostatic discharge path circuit, wherein the electrostatic discharge event detecting circuit is configured to detect the electrostatic energy at the first input node or the second input node, and to turn on the electrostatic discharge path circuit when the electrostatic discharge event detecting circuit determines that the electrostatic discharge event occurs in the driver circuit according to the electrostatic energy.

10. The electrostatic discharge protection circuit according to claim 9, wherein the electrostatic discharge event detecting circuit includes:
a charging time detecting circuit connected to the first input node, and configured to output a detection time startup signal when the charging time detecting circuit detects and determines that the electrostatic energy at the first input node is coupled to a startup voltage level after a charging time has elapsed;
a voltage detecting circuit connected to the first input node, and configured to output an overvoltage signal when the voltage detecting circuit detects and determines that a voltage level of the electrostatic energy at the first input node reaches the startup voltage level; and
an electrostatic discharge starting circuit connected to the charging time detecting circuit, the voltage detecting circuit and the electrostatic discharge path circuit, and configured to drive the electrostatic discharge path circuit according to the detection time startup signal and the overvoltage signal.

11. The electrostatic discharge protection circuit according to claim 10, wherein the charging time detecting circuit includes a plurality of charged components, and the electrostatic discharge starting circuit includes a startup switch component and a driving switch component;
wherein the plurality of charged components are connected in series between the first input node and the second input node, a control terminal of the startup switch component is connected to a voltage node between two of the plurality of charged components, and a first terminal of the startup switch component and an input terminal of the voltage detecting circuit are connected to the first input node;
wherein an output terminal of the voltage detecting circuit is connected to a control terminal of the driving switch component, a first terminal of the driving switch component is connected to a second terminal of the startup switch component, and a second terminal of the driving switch component is connected to the control terminal of the electrostatic discharge path circuit.

12. The electrostatic discharge protection circuit according to claim 10, wherein the charging time detecting circuit includes a plurality of charged components, and the electrostatic discharge starting circuit includes a startup switch component;
wherein the plurality of charged components are connected in series between the first input node and the second input node, and an input terminal of the voltage detecting circuit is connected to the first input node;
wherein a control terminal of the startup switch component is connected to a voltage node between two of the plurality of charged components, a first terminal of the startup switch component is connected to an output terminal of the voltage detecting circuit, and a second terminal of the startup switch component is connected to the control terminal of the electrostatic discharge path circuit.

13. The electrostatic discharge protection circuit according to claim 10, wherein the charging time detecting circuit includes a plurality of charged components, and the electrostatic discharge starting circuit includes a startup switch component;
wherein the plurality of charged components are connected in series between the first input node and the second input node, a first terminal of the startup switch component is connected to the first input node, a control terminal of the startup switch component is connected to a voltage node between two of the plurality of charged components, a second terminal of the startup switch component is connected to an input terminal of the voltage detecting circuit, and an output terminal of the voltage detecting circuit is connected to the control terminal of the electrostatic discharge path circuit.

14. An integrated circuit having an electrostatic discharge protection mechanism, comprising:
a driver circuit including a plurality of input terminals, wherein the plurality of input terminals includes a plurality of power receiving terminals; and
an electrostatic discharge clamp circuit connected to the plurality of power receiving terminals and an external ground terminal, and configured to:
detect a power signal at each of the plurality of power receiving terminals to determine whether or not an electrostatic discharge event occurs in the driver circuit; and
guide electrostatic energy inside the integrated circuit to the electrostatic discharge clamp circuit and then guide the electrostatic energy to the external ground terminal outside the integrated circuit when the electrostatic discharge event occurs in the driver circuit.

15. The integrated circuit according to claim 14, wherein the plurality of power receiving terminals include a first power receiving terminal and a second power receiving terminal, the first power receiving terminal is connected to a first input node and the first input node is connected to a first input power source, the second power receiving terminal is connected to a second input node and the second input node is connected to a second input power source, and the electrostatic discharge clamp circuit includes:
an electrostatic discharge path circuit connected between the first input node and the second input node; and
an electrostatic discharge event detecting circuit connected between the first input node and the second input node and connected to a control terminal of the electrostatic discharge path circuit, wherein the electrostatic discharge event detecting circuit is configured to detect the power signal at the first input node or the second input node, and to turn on the electrostatic discharge path circuit when the electrostatic discharge event detecting circuit determines that the electrostatic discharge event occurs in the driver circuit according to the power signal that is detected.

16. The integrated circuit according to claim 15, wherein the electrostatic discharge event detecting circuit includes:
a charging time detecting circuit connected to the first input node, and configured to output a detection time startup signal when the charging time detecting circuit detects and determines that the power signal at the first input node is coupled to a startup voltage level after a charging time has elapsed;
a voltage detecting circuit connected to the first input node, and configured to output an overvoltage signal when the voltage detecting circuit detects and determines that the power signal reaches the startup voltage level; and
an electrostatic discharge starting circuit connected to the charging time detecting circuit, the voltage detecting circuit and the electrostatic discharge path circuit, and configured to drive the electrostatic discharge path circuit according to the detection time startup signal and the overvoltage signal.

17. The integrated circuit according to claim 16, wherein the charging time detecting circuit includes a plurality of charged components, and the electrostatic discharge starting circuit includes a startup switch component and a driving switch component;
wherein the plurality of charged components are connected in series between the first input node and the second input node, a control terminal of the startup switch component is connected to a voltage node between two of the plurality of charged components, and a first terminal of the startup switch component and an input terminal of the voltage detecting circuit are connected to the first input node;
wherein an output terminal of the voltage detecting circuit is connected to a control terminal of the driving switch component, a first terminal of the driving switch component is connected to a second terminal of the startup switch component, and a second terminal of the driving switch component is connected to the control terminal of the electrostatic discharge path circuit.

18. The integrated circuit according to claim 16, wherein the charging time detecting circuit includes a plurality of charged components, and the electrostatic discharge starting circuit includes a startup switch component;
wherein the plurality of charged components are connected in series between the first input node and the second input node, and an input terminal of the voltage detecting circuit is connected to the first input node;
wherein a control terminal of the startup switch component is connected to a voltage node between two of the plurality of charged components, a first terminal of the startup switch component is connected to an output terminal of the voltage detecting circuit, and a second terminal of the startup switch component is connected to the control terminal of the electrostatic discharge path circuit.

19. The integrated circuit according to claim 16, wherein the charging time detecting circuit includes a plurality of charged components, and the electrostatic discharge starting circuit includes a startup switch component;
wherein the plurality of charged components are connected in series between the first input node and the second input node, a first terminal of the startup switch component is connected to the first input node, a control terminal of the startup switch component is connected to a voltage node between two of the plurality of charged components, a second terminal of the startup switch component is connected to an input terminal of the voltage detecting circuit, and an output terminal of the voltage detecting circuit is connected to the control terminal of the electrostatic discharge path circuit.
